(19) United States
(12) Patent Application Publication
(10) Pub. No.: US 2014/0326296 A1
(43) Pub. Date: Nov. 6, 2014

(54) SOLAR CELL AND METHOD OF FABRICATING THE SAME

(71) Applicant: LG INNOTEK CO., LTD., Seoul (KR)

(72) Inventor: Gi Gon Park, Seoul (KR)

(21) Appl. No.: 14/357,718

(22) PCT Filed: Nov. 8, 2012
(86) PCT No.: PCT/KR2012/009424

§ 371 Date: May 12, 2014

(30) Foreign Application Priority Data
Nov. 11, 2011 (KR) 10-2011-0117927

(51) Int. Cl. H01L 31/0216

(52) U.S. Cl. CPC H01L 31/02167
USPC 136/252

(57) ABSTRACT

Disclosed are a solar cell and a method of fabricating the same. The solar cell includes a back electrode layer on a support substrate, a light absorbing layer on the back electrode layer, a buffer layer on the light absorbing layer, and a front electrode layer on the buffer layer.

### TECHNICAL FIELD

The embodiment relates to a solar cell and a method of fabricating the same.

### BACKGROUND ART

Solar cells may be defined as devices to convert light energy into electric energy through a photovoltaic effect of generating electrons when light is incident onto a P-N junction diode. The solar cell may be classified into a silicon solar cell, a compound semiconductor solar cell mainly including a group I-III-VI compound or a group III-V compound, a dye-sensitized solar cell, and an organic solar cell according to materials constituting the junction diode.

A solar cell made from CIGS (CuInGaSe), which is one of group I-III-VI chalcopyrite-based compound semiconductors, represents superior light absorption, higher photoelectric conversion efficiency with a thin thickness, and superior electro-optic stability, so the CIGS solar cell is spotlighted as a substitute for a conventional silicon solar cell.

In general, a conventional CIGS thin film solar cell has the structure of soda line glass/Mo/CIGS/CdS (ZnS)/ZnO/ITO/Al. In the above structure, the CdS layer serves as a buffer layer to minimize the damage of the CIGS layer when the ZnO layer is deposited through the sputtering process, and to reduce the difference in the lattice constant and the bandgap between the CIGS layer and the ZnO layer, thereby increasing the efficiency of the CIGS thin film solar cell.

However, Cd has severe toxicity and represents a lower bandgap of 2.4 eV so that the light absorption is reduced in the CIGS layer. Accordingly, a novel buffer layer to be substituted for the CdS has been required. Alternatively, materials such as ZnS, Zn(O, S, OH), (Zn, Mg)O, and In₂S₃ have been studied. However, the ZnS has the high bandgap of about 3.7 eV.

### DISCLOSURE OF INVENTION

### Technical Problem

The embodiment provides a solar cell having improved photoelectric conversion efficiency and a method of fabricating the same.

### Solution to Problem

According to the embodiment, there is provided a solar cell including a back electrode layer on a support substrate, a light absorbing layer on the back electrode layer, a buffer layer on the light absorbing layer, and a front electrode layer on the buffer layer. The buffer layer has bandgap energy gradually reduced toward a bottom surface thereof.

According to the embodiment, there is provided a method of fabricating a solar cell including forming a back electrode layer on a support substrate, forming a light absorbing layer on the back electrode layer, forming a buffer layer on the light absorbing layer, and forming a front electrode layer on the buffer layer. The buffer layer has bandgap energy gradually reduced toward a bottom surface thereof.

### Advantageous Effects of Invention

As described above, according to the embodiment, the solar cell includes the buffer layer having bandgap energy that is gradually varied. Accordingly, the solar cell according to the embodiment can easily transfer electrons and/or holes formed by the external solar light to the back electrode layer and the front electrode layer, so that improved power generation efficiency can be represented. In addition, since the buffer layer according to the embodiment has bandgap higher than that of a conventional buffer layer, the transmittance of the solar light can be improved.

### BRIEF DESCRIPTION OF DRAWINGS

FIG. 1 is a sectional view showing a solar cell according to the first embodiment;

FIG. 2 is a graph showing the bandgap energy of each layer according to the first embodiment;

FIG. 3 is a graph showing the variation in the bandgap energy of the buffer layer according to the contents of oxygen (O) and sulfur (S);

FIG. 4 is a graph showing the content of sulfur (S) in the buffer layer according to the first embodiment;

FIG. 5 is a sectional view showing the solar cell according to the second embodiment; and

FIGS. 6 to 10 are sectional views showing a method of fabricating the solar cell according to the embodiment.

### MODE FOR THE INVENTION

In the description of the embodiments, it will be understood that, when a substrate, a layer, a film, or an electrode is referred to as being “on” or “under” another substrate, another layer, another film, or another electrode, it can be “directly” or “indirectly” on the other substrate, the other layer, the other film, or the other electrode, or one or more intervening layers may also be present. Such a position of each component has been described with reference to the drawings. The thickness and size of each component shown in the drawings may be exaggerated, omitted or schematically drawn for the purpose of convenience or clarity. In addition, the size of elements does not utterly reflect an actual size.

The term “HOMO (The Highest Occupied Molecular Orbital) level” used in the disclosed refers to the highest energy level of a valance band. The term “LUMO (The Lowest Occupied Molecular Orbital) level” used in the disclosed refers to the lowest energy level of a conduction band. The term “bandgap” used in the disclosed refers to the difference between HOMO level energy and LUMO level energy.

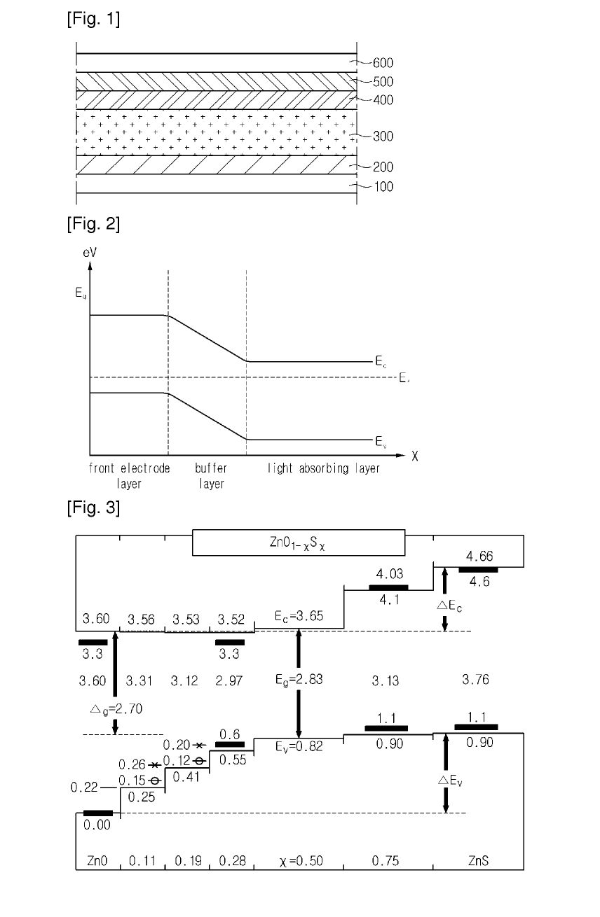

FIG. 1 is a sectional view showing a solar cell according to the first embodiment. Referring to FIG. 1, the solar cell according to the embodiment includes a support substrate 100, a back electrode layer 200, a light absorbing layer 300, a buffer layer 400, a high resistance buffer layer 500, and a front electrode layer 600.

The support substrate 100 has a plate shape and supports the back electrode layer 200, the light absorbing layer 300, the buffer layer 400, the high resistance buffer layer 500, and the front electrode layer 600.

The support substrate 100 may include an insulator. The support substrate 100 may include a glass substrate, a plastic substrate, or a metallic substrate. In more detail, the support substrate 100 may include a soda lime glass substrate.

The support substrate 100 may be rigid or flexible. In more detail, the support substrate 100 may be a flexible substrate. For example, the support substrate 100 may include polymer having flexibility. The front electrode layer 600 of the solar cell according to the embodiment not only represents a superior mechanical characteristic, but superior flexibility. If the substrate 100 includes a flexible material, the solar cell according to the embodiment may be easily used in a region requiring the flexible characteristic.

The back electrode layer 200 is provided on the support substrate 100. The back electrode layer 200 is a conductive layer. The back electrode layer 200 may include one selected from the group consisting of molybdenum (Mo), gold (Au), aluminum (Al), chrome (Cr), tungsten (W), and copper (Cu). Among them, Mo represents a less thermal expansion coefficient difference from the support substrate 100 as compared with that of another element, so that Mo has a superior adhesive strength to prevent delamination from the support substrate 100.

The light absorbing layer 300 is provided on the back electrode layer 200. The light absorbing layer 300 includes a group I-III-VI compound. For example, the light absorbing layer 300 may have a Cu(In,Ga)Se₂ (CIGS) crystal structure, a Cu(In)Se₂ crystal structure, or a Cu(Ga)Se₂ crystal structure. The light absorbing layer 300 has an energy bandgap in the range of about 1 eV to about 1.8 eV, but the embodiment is not limited thereto.

The buffer layer 400 is provided on the light absorbing layer 300. The thickness of the buffer layer 400 may be in the range of about 15 nm to about 70 nm, but the embodiment is not limited thereto. The buffer layer 400 may be represented through following chemical equation 1.

ZnO₁₋ₓSₓ(0.2≦X≦0.8) [Chemical Equation 1]

In addition, the bandgap energy of the buffer layer 400 may have the value of about 2.83 eV to about 3.3 eV. Accordingly, the buffer layer 400 according to the embodiment may have the bandgap energy (about 2.2 eV to about 2.4 eV) greater than that of the conventional buffer layer, and the transmittance of the buffer layer 400 may be improved.

The bandgap energy of the buffer layer 40 may be gradually aligned according to the internal positions of the buffer layer 40. In more detail, the bandgap energy of the buffer layer 40 may be gradually reduced from the interfacial surface between the buffer layer 400 and the front electrode layer 600 toward the interfacial surface between the buffer layer 400 and the light absorbing layer 300. For example, the bandgap energy of the buffer layer 400 is about 3.3 eV at the interfacial surface between the buffer layer 400 and the front electrode layer 600. The bandgap energy of the buffer layer 400 is gradually reduced toward the light absorbing layer 300, so that the bandgap energy of the buffer layer 400 may represent the value of about 2.8 eV at the interfacial surface between the buffer layer 400 and the light absorbing layer 300, but the embodiment is not limited thereto.

Referring to FIG. 2, the bandgap energy of the buffer layer 400 is less than the bandgap energy of the front electrode layer 600, and greater than the bandgap energy of the light absorbing layer 300. For example, when the bandgap energy of the buffer layer 400, the bandgap energy of the front electrode layer 600, and the bandgap energy of the light absorbing layer 300 are the second bandgap energy, the first bandgap energy, and the third bandgap energy, respectively, the second bandgap energy is greater than the third bandgap energy, and lower than the first bandgap energy.

In other words, the bandgap energy of the buffer layer 400 according to the embodiment has an intermediate value between the bandgap energies of the front electrode layer 600 and the light absorbing layer 300. The bandgap energy is gradually reduced from the front electrode layer 600 to the light absorbing layer 300. Accordingly, the solar cell according to the embodiment has the buffer layer 400 having the sequential potential barrier. Therefore, in the solar cell according to the embodiment, the electrons and/or holes formed by the solar light can be easily transferred to the back electrode layer 200 and the front electrode layer 600 and can represent improved power generation efficiency.

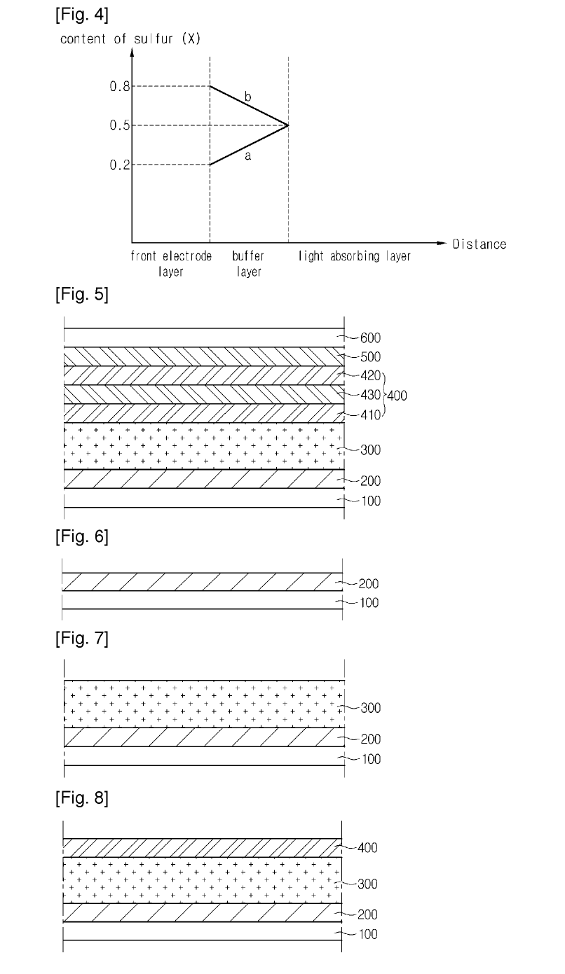

According to the solar cell of the embodiment, the buffer layer 400 having the sequential bandgap energy levels may be fabricated by adjusting the contents of oxygen and sulfur in the buffer layer 400. FIGS. 3 and 4 are graphs showing the variation in the bandgap energy of the buffer layer 400 according to the contents of the oxygen and sulfur.

According to the embodiment, the content of the sulfur in the buffer layer 400 may be increased from the interfacial surface between the buffer layer 400 and the front electrode layer 600 toward the interfacial surface between the buffer layer 400 and the light absorbing layer 300. For example, as the content of the sulfur (value of X) is gradually increased from about 0.2 toward about 0.5 in chemical equation 1 (see a of FIG. 4), the content of the oxygen may be gradually reduced from about 0.8 toward about 0.5. Therefore, the bandgap energy of the buffer layer 400 may be gradually reduced from the interfacial surface between the buffer layer 400 and the front electrode layer 600 toward the interfacial surface between the buffer layer 400 and the light absorbing layer 300.

According to another embodiment, the content of the sulfur in the buffer layer 400 may be gradually reduced from the interfacial surface between the buffer layer 400 and the front electrode layer 600 toward the interfacial surface between the buffer layer 400 and the light absorbing layer 300. For example, in Chemical Equation 1, as the content of the sulfur (the value of X) is reduced from about 0.8 to about 0.5 (see b of FIG. 4), the content of the oxygen may be gradually increased from about 0.2 to about 0.5. Therefore, the bandgap energy of the buffer layer 400 may be gradually reduced from the interfacial surface between the buffer layer 400 and the front electrode layer 600 toward the interfacial surface between the buffer layer 400 and the light absorbing layer 300.

Meanwhile, only the buffer layer 400 provided in the form of a single layer has been described, but the embodiment is not limited thereto. In other words, the buffer layer 400 according to the embodiment may include a plurality of buffer layers. For example, the buffer layer 400 may include a first buffer layer provided on the light absorbing layer 300 and a second buffer layer provided on the first buffer layer. In this case, the bandgap energy of the second buffer layer is greater than the bandgap energy of the first buffer layer, and the bandgap energies of the second buffer layer and the first buffer layer may have sequential values.

The high resistance buffer layer 500 is provided on the buffer layer 400. The high resistance buffer layer 500 may include iZnO, which is zinc oxide not doped with impurities. The high resistance buffer layer 500 has an energy bandgap in the range of about 3.1 eV to about 3.3 eV, but the embodiment is not limited thereto. In addition, the high resistance buffer layer 500 may be omitted.

The front electrode layer 600 may be provided on the light absorbing layer 300. For example, the front electrode layer 600 may directly make contact with the high resistance buffer layer 500 formed on the light absorbing layer 300.

The front electrode layer 600 may include a transmissive conductive material. In addition, the front electrode layer 600 may have the characteristic of the N type semiconductor. In this case, the front electrode layer 600 may form an N type semiconductor layer together with the buffer layer 400 to form a PN junction with the light absorbing layer 300 which is a P type semiconductor layer. For example, the front electrode layer 600 may include Al-doped zinc oxide (AZO). The front electrode layer 600 may have a thickness of about 100 nm to about 500 nm.

FIG. 5 is a sectional view showing a solar cell according to a second embodiment. Referring to FIG. 5, the solar cell according to the second embodiment includes a first buffer layer 410 provided on the light absorbing layer 300 and a second buffer layer 420 provided on the first buffer layer 410. The bandgap energy of the second buffer layer 420 is greater than that of the first buffer layer 410, and the second buffer layer 420 may be expressed by following chemical equation 1. In addition, as described in the first embodiment, the bandgap energy of the second buffer layer 420 may be gradually reduced from the interfacial surface between the second buffer layer 420 and the front electrode layer 600 toward the interfacial surface between the second buffer layer 420 and the first buffer layer 410.

ZnO₁₋ₓSₓ(0.2≦X≦0.8) [Chemical Equation 1]

As described above, the first buffer layer 410 has the bandgap energy value smaller than that of the second buffer layer 420. For example, the bandgap energy of the first buffer layer 410 may be less than about 2.83 eV. In more detail, the first buffer layer 410 may have the bandgap energy of about 2.0 eV to about 2.83 eV, but the embodiment is not limited thereto.

The first buffer layer 410 may include a cadmium sulfide (CdS) layer. The CdS layer may have a thickness of about 1 nm to about 10 nm, so that the toxicity of CdS can be minimized. In addition, when forming the cadmium sulfide (CdS) layer, a part of cadmium ions (Cd²⁺) may be diffused into the light absorbing layer 300. In other words, the cadmium ions (Cd²⁺) may be diffused into copper (Cu) vacancies formed in the light absorbing layer 300. Accordingly, the cadmium ions (Cd²⁺) may be provided in the vicinity of the surface of the light absorbing layer 300. As the cadmium ions (Cd²⁺) may be diffused into a copper (Cu) vacancy formed in the light absorbing layer 300, the defect of the light absorbing layer 300 may be removed, and the efficiency of the light absorbing layer 300 may be increased.

In addition, a third buffer layer 430 may be additionally interposed between the first and second buffer layers 410 and 440. For example, the third buffer layer 430 may include a CdZnS layer. In other words, parts of the first and second buffer layers 410 and 420 react to each other to form the CdZnS layer, so that the bandgap energy can be easily aligned.

FIGS. 6 to 10 are sectional views showing the method of fabricating the solar cell according to the embodiment. Hereinafter, the description of the present method of fabricating the solar cell will be made by making reference to the above description of the solar cell.

Referring to FIG. 6, a back electrode layer 200 is formed on the support substrate 100. The back electrode layer 200 may be formed through a physical vapor deposition (PVD) scheme or a plating scheme.

Thereafter, referring to FIG. 7, the light absorbing layer 300 is formed on the back electrode layer 200. For example, the light absorbing layer 300 may be formed through various schemes such as a scheme of forming a Cu(In,Ga)Se₂ (CIGS) based light absorbing layer 300 by simultaneously or separately evaporating Cu, In, Ga, and Se and a scheme of performing a selenization process after a metallic precursor layer has been formed.

Regarding the details of the selenization process after the formation of the metallic precursor layer, the metallic precursor layer is formed on the back electrode layer 200 through a sputtering process employing a Cu target, an In target, or a Ga target. Thereafter, the metallic precursor layer is subject to the selenization process so that the Cu (In, Ga) Se₂ (CIGS) based light absorbing layer 300 is formed.

In addition, the sputtering process employing the Cu target, the In target, and the Ga target and the selenization process may be simultaneously performed.

Alternatively, a CIS or a CIG based light absorbing layer 300 may be formed through the sputtering process employing only Cu and In targets or only Cu and Ga targets and the selenization process.

Thereafter, referring to FIG. 8, the buffer layer 400 is formed on the light absorbing layer 300. The buffer layer 400 may be formed through various schemes of fabricating a buffer layer of a solar cell, which have been generally known to those skilled in the art. For example, the buffer layer 400 may be formed through one selected from among sputtering, evaporation, chemical vapor deposition (CVD), metal organic chemical vapor deposition (MOCVD), close-spaced sublimation (CSS), spray pyrolysis, chemical spraying, screen printing, vacuum-free liquid-phase film deposition, chemical-bath deposition (CBD), vapor transport deposition (VTD), atomic layer deposition (ALD), and electro-deposition schemes. In more detail, the buffer layer 400 may be fabricated through the CBD scheme, an ALD scheme, or an MOCVD scheme.

According to one embodiment, the buffer layer 400 may be formed through the following CBD scheme. As the sources of zinc (Zn) and sulfur (S), zinc sulfuric acid (ZnSO), and thiurea (SC(NH₂)₂), which have the aqueous solution state, are used, and ammonia (NH₃) is used as a complex compound and a pH control agent. In addition, to accelerate the production of zinc ions in the reaction solution, a proper amount of a hydrozinehydrate solution may be added. In other words, in order to grow a ZnS thin film, aqueous-solution-state reagents, that is, zinc sulfuric acid (ZnSO), ammonia (NH₃), hydrozinehydrate, and thiurea (SC(NH₂)₂), are sequentially added in a reaction vessel having a proper amount of deionized water therein. In this case, the temperature of the support substrate 100 having the light absorbing layer 300 can be adjusted to the temperature of about 50° C. to about 90° C. by using the heater installed in the reaction vessel.

In addition, the buffer layer 400 having the sequential bandgap energy can be formed by adjusting the reaction temperature at two steps or more. For example, the reaction of oxygen (O) is mainly performed under the temperature condition of about 50° C. to about 60° C., and the reaction of sulfur (S) is mainly performed under the temperature condition of about 70° C. to about 90° C., so that the buffer layer 400 having the sequential bandgap energy can be fabricated.

According to another embodiment, when the buffer layer 400 is fabricated by using an ALD scheme or an MOCVD scheme, the bandgap energy of the buffer layer 400 can be gradually adjusted by adjusting the partial pressure of the reaction gas.

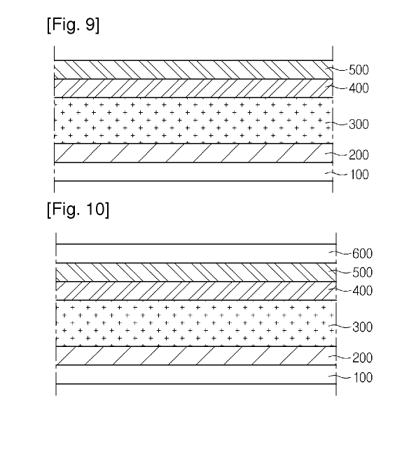

Referring to FIGS. 9 and 10, a high resistance buffer layer 500 is sequentially formed on the buffer layer 400. The high resistance buffer layer 500 may be formed on the buffer layer 400 by depositing zinc oxide through a sputtering process. In addition, the front electrode layer 600 may be formed through an RF sputtering scheme using a ZnO target, a reactive sputtering scheme using a Zn target, and a MOCVD scheme.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising:
a back electrode layer on a support substrate;
a light absorbing layer on the back electrode layer;
a buffer layer on the light absorbing layer; and
a front electrode layer on the buffer layer,
wherein the buffer layer has bandgap energy gradually reduced toward a bottom surface thereof.

2. The solar cell of claim 1, wherein the buffer layer is expressed by following chemical equation 1,
ZnO₁₋ₓSₓ(0.2≦X≦0.8). Chemical Equation 1

3. The solar cell of claim 1, wherein the bandgap energy of the buffer layer is gradually reduced from an interfacial surface between the buffer layer and the front electrode layer toward an interfacial surface between the buffer layer and the light absorbing layer.

4. The solar cell of claim 3, wherein the bandgap energy of the buffer layer is in a range of 2.83 eV to 3.3 eV.

5. The solar cell of claim 2, wherein a content of the sulfur (S) is varied according to positions in the buffer layer.

6. The solar cell of claim 5, wherein the content of the sulfur (S) is reduced from 0.8 to 0.5 toward the bottom surface of the buffer layer.

7. The solar cell of claim 5, wherein the content of the sulfur (S) is increased from 0.2 to 0.5 toward the bottom surface of the buffer layer.

8. The solar cell of claim 1, wherein the buffer layer comprises a first buffer layer on the light absorbing layer and a second buffer layer on the first buffer layer, and bandgap energy of the second buffer layer is higher than bandgap energy of the first buffer layer.

9. The solar cell of claim 1, wherein the bandgap energy of the buffer layer is higher than bandgap energy of the light absorbing layer, and lower than bandgap energy of the front electrode layer.

10. The solar cell of claim 1, wherein the buffer layer has a thickness in a range of 15 nm to 70 nm.

11. The solar cell of claim 8, wherein the first buffer layer comprises a cadmium sulfide (CdS) layer, the second buffer layer is expressed by following Chemical Equation 1,
ZnO₁₋ₓSₓ(0.2≦X≦0.8). Chemical Equation 1

12. The solar cell of claim 11, wherein cadmium ions (Cd2+) of cadmium sulfide (CdS) are diffused into copper (Cu) vacancies provided at a portion of the light absorbing layer making contact with the first buffer layer.

13. The solar cell of claim 11, wherein the buffer layer further comprises a third buffer layer formed through reaction of the first and second buffer layers while being interposed between the first and second buffer layers, and the third buffer layer comprises a CdZnS layer.

14-17. (canceled)

18. The solar cell of claim 8, wherein the bandgap energy of the first buffer layer has the bandgap energy of about 2.0 eV to about 2.83 eV.

19. The solar cell of claim 11, wherein the cadmium sulfide layer has a thickness of about 1 nm to about 10 nm.
